(19) United States
(12) Patent Application Publication
(10) Pub. No.: US 2003/0135336 A1
(43) Pub. Date: Jul. 17, 2003

(54) Body data measuring apparatus

(76) Inventors: Masahiro Inoue, Nara (JP); Kazutoshi Nagai, Nara (JP); Toshiyuki Tanaka, Nara (JP); Koji Yoshimoto, Nara (JP)

Correspondence Address: RATNERPRESTIA, P O BOX 980, VALLEY FORGE, PA, 19482-0980, US

(21) Appl. No.: 10/317,344

(22) Filed: Dec. 10, 2002

(30) Foreign Application Priority Data
Dec. 17, 2001 (JP) 2001-382661
Apr. 10, 2002 (JP) 2002-107627
Oct. 9, 2002 (JP) 2002-296240

(51) Int. Cl. G01R 15/00; G06F 19/00

(52) U.S. Cl. 702/57

(57) ABSTRACT

An apparatus comprises a body support base and a handgrip unit connected with a cable, and a storage unit of either cylindrical shape or a recessed potion disposed to the body support base for storage of the cable and the handgrip unit. The structure conceals the stored cable, so as to improve outward appearance and convenience of use including portability and ease of cleaning when not in use, and to avoid the cable from collecting dust.

### FIELD OF THE INVENTION

The present invention relates to a body data measuring apparatus for computing data on a living human body based on body impedance.

### BACKGROUND OF THE INVENTION

Body data measuring apparatuses such as the one disclosed in Japanese Patent Application Non-Examined Publication No. H07-59744, are the type generally known hitherto. FIG. 23 depicts a general view of a body data measuring apparatus of the prior art.

The apparatus has hand electrodes 103 on handgrips 104 of main body 122 that can be held with both hands, and another set of electrodes 101 on foot electrode unit 121, which is connected to the main body 122 with cable 107. A person under measurement inputs his/her data on standing height, weight, and sex using a group of keys 105, holds the main body 122 of the apparatus with both hands after confirmation of the data on display panel 106, steps on the foot electrode unit 121, and takes a measurement with his/her body kept in a pre-directed posture. During this moment, individual palms and soles of the feet come in contact with the electrodes 103 and 101 provided on the handgrips 104 and the foot electrode unit 121 respectively. As a result, the main body 122 measures impedance between the hands and the feet. The main body 122 then generates data on the body by computing it based on the impedance and the data input by the person under the measurement.

In the above-described body data measuring apparatus of the prior art, however, the apparatus's main body 122 and the foot electrode unit 121 come apart from each other, and they may become disorderly when not in use, unless they are put together by some means. The same is also the case with the cable.

In addition, the cable tends to collect dust because it is exposed at all times. Although stain on the apparatus's main body can be wiped clean easily, fouling on the cable, which is generally flexible, is difficult to remove. It may become very annoying task to remove the fouling, especially when the apparatus is used for a long period of time.

Moreover, the cable becomes obstructive when the apparatus is being carried, as the cable may catch a foot or any other object if it dangles while being moved.

### SUMMARY OF THE INVENTION

A body data measuring apparatus of the present invention comprises a holder for organizing a handgrip unit and a body support base, both provided with electrodes. The holder stores the handgrip unit when the apparatus is not in use.

### BRIEF DESCRIPTION OF THE DRAWINGS

FIG. 1 is a general view of a body data measuring apparatus according to a first exemplary embodiment of the present invention.

FIG. 2 is a block diagram of the body data measuring apparatus according to the first exemplary embodiment of the invention.

FIG. 3 is an expository illustration showing how measurement is made according to the first exemplary embodiment of the invention.

FIG. 4 is an overall view of the body data measuring apparatus when a cable and a handgrip unit are stored in a storage unit according to the first exemplary embodiment of the invention.

FIG. 5 is a front view of a body data measuring apparatus according to one of second and seventh exemplary embodiments of the invention, as viewed from the storage unit side.

FIG. 6 is a right-side view of the same apparatus in the vicinity of the storage unit as viewed from a direction of arrow A in FIG. 5.

FIG. 7 is a sectional view as taken along a line B-B of FIG. 5.

FIG. 8 is a general view of a body data measuring apparatus according to a third exemplary embodiment of the present invention.

FIG. 9 is an exploded view of a storage unit of a body data measuring apparatus according to a fourth exemplary embodiment of the present invention.

FIG. 10 is a general view of a body data measuring apparatus according to a fifth exemplary embodiment of the invention, depicting a position of a storage unit as is being attached to a body support base.

FIG. 11 is a general view of a body data measuring apparatus according to a sixth exemplary embodiment of the present invention.

FIG. 12 is a block diagram of the body data measuring apparatus according to the sixth exemplary embodiment of the invention.

FIG. 13 is an expository illustration showing how measurement is made according to the sixth exemplary embodiment of the invention.

FIG. 14 is a schematic view depicting a spiral cable and a wire in a position of measurement according to the sixth exemplary embodiment of the invention.

FIG. 15 is another schematic view depicting the spiral cable and the wire in their stored position according to the sixth exemplary embodiment of the invention.

FIG. 16 is a schematic view depicting a fastener of the wire in the body data measuring apparatus of an eighth exemplary embodiment of the present invention.

FIG. 17 is a general view of a body data measuring apparatus according to a ninth exemplary embodiment of the present invention.

FIG. 18 is an expository illustration showing how measurement is made according to the ninth exemplary embodiment of the invention.

FIG. 19 is a block diagram of the body data measuring apparatus according to the ninth exemplary embodiment of the invention.

FIG. 20 is an overall view of a handgrip unit of a body data measuring apparatus according to a tenth exemplary embodiment of the present invention.

FIG. 21 is an expository illustration showing the body data measuring apparatus in use according to the tenth exemplary embodiment of the invention.

FIG. 22 is another expository illustration showing the body data measuring apparatus when not in use, according to the tenth exemplary embodiment of the invention.

FIG. 23 is a general view of a body data measuring apparatus of the prior art.

### DESCRIPTION OF THE PREFERRED EMBODIMENTS

Exemplary embodiments of the present invention will be described hereinafter with reference to the accompanying drawings.

In the following exemplary embodiments, percent of body fat is taken as an example of the body data in order to illustrate the invented apparatus more comprehensibly. However, it can be of any kind of apparatus that measures bone mineral density, muscular amount, and degree of muscle fatigue, for example, without departing the spirit and scope of this invention so long as it measures and computes physical data based upon body impedance and other information representing physical characteristics of a human subject under measurement. In these exemplary embodiments, like reference numerals are used throughout to represent components of like structure.

(First Exemplary Embodiment)

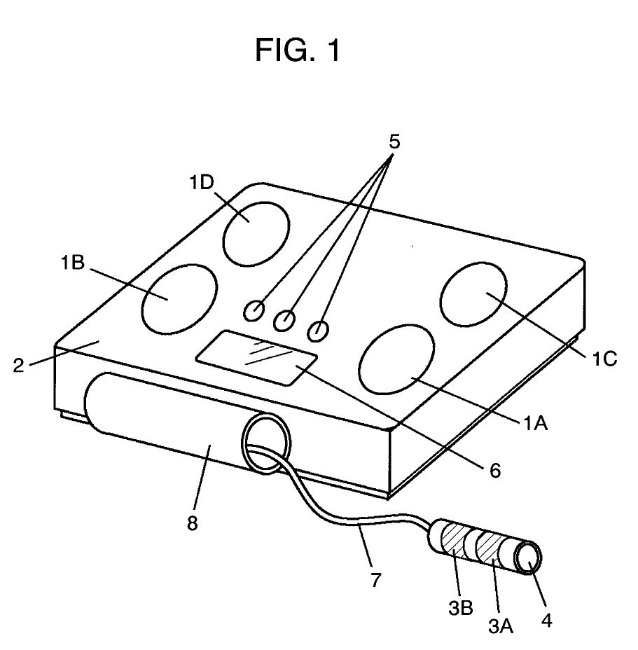

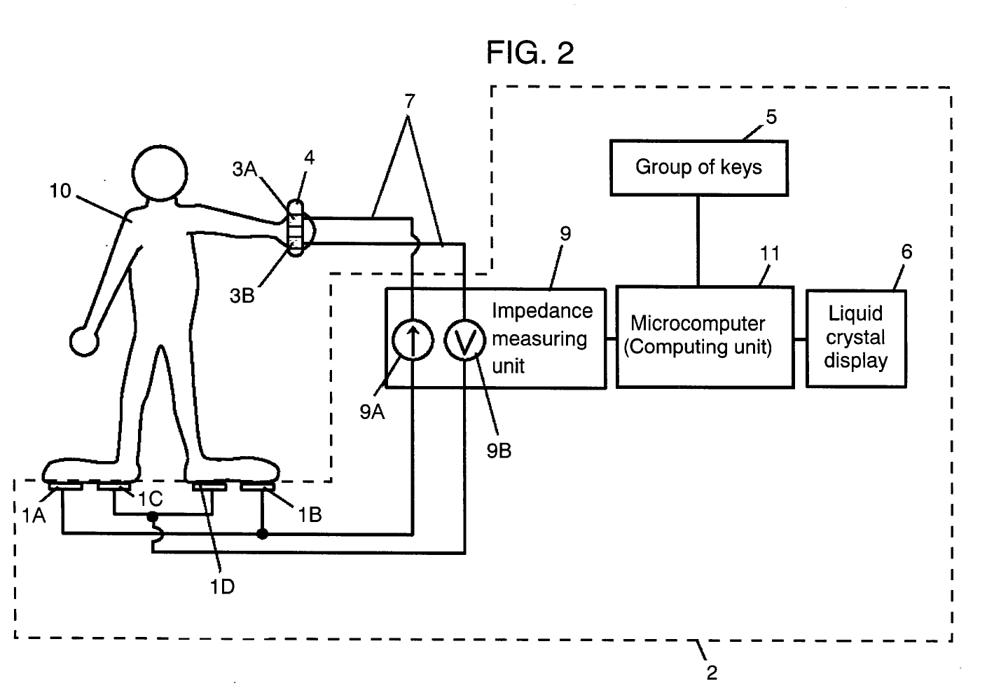

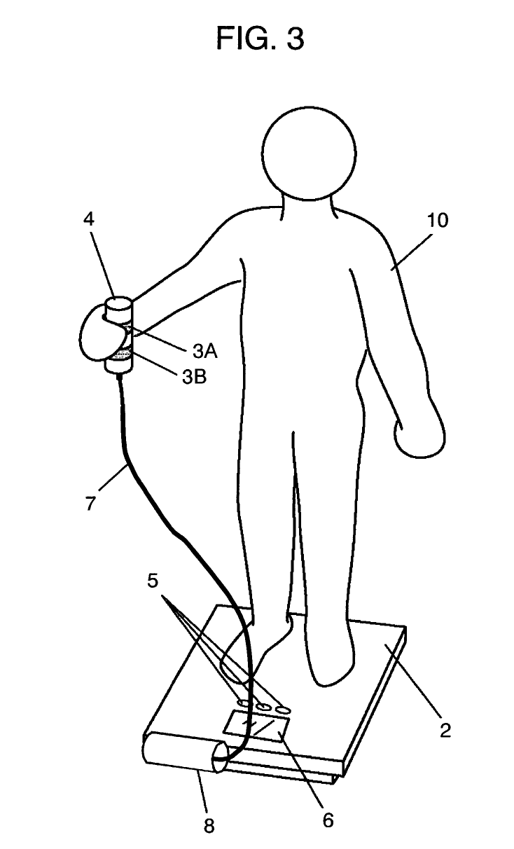

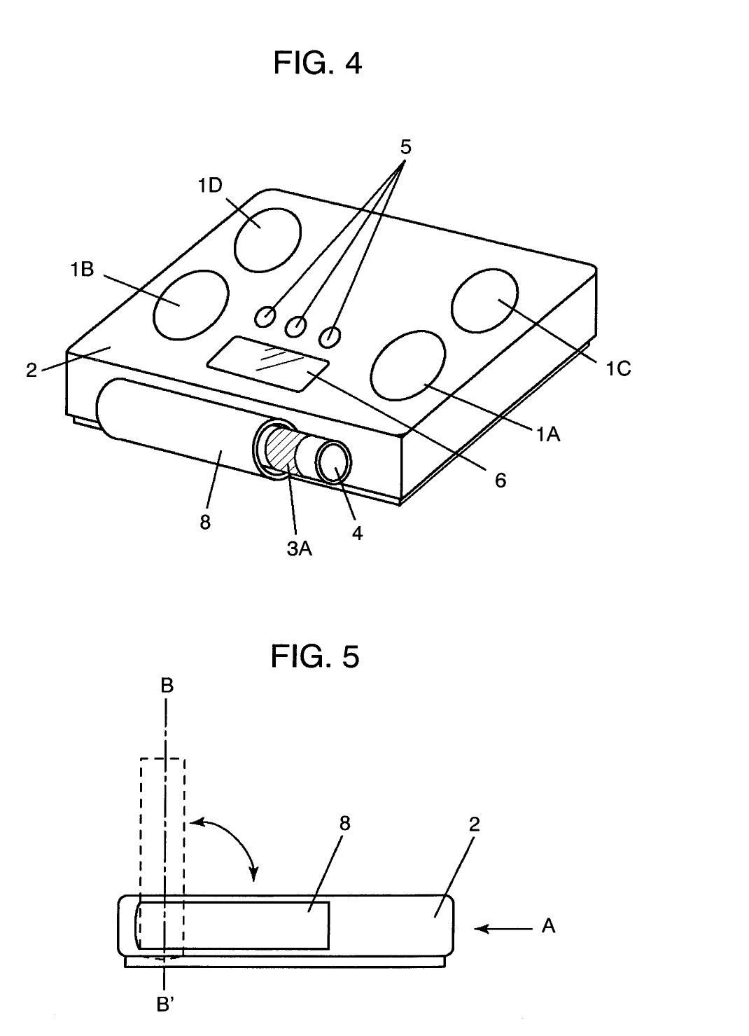

FIG. 1 is a general view of a body data measuring apparatus (hereafter referred to as apparatus) according to the first exemplary embodiment of this invention, FIG. 2 is a block diagram of the apparatus, FIG. 3 is an expository illustration showing how measurement is made, and FIG. 4 is an overall view of the apparatus when cable 7 and handgrip unit 4 are stored in storage unit 8.

The apparatus of this exemplary embodiment has body support base 2 (hereinafter referred to as support base) comprising an enclosure of the apparatus' main body, and it is provided with foot electrodes 1A, 1B, 1C, and 1D. In this exemplary embodiment, the electrodes 1A and 1B are connected together electrically, to serve one end of a pair of electric terminals of constant-current power supply 9A. Likewise, the electrodes 1C and 1D are also connected together electrically, to serve one end of a pair of electric terminals of body resistance potential detector 9B. The constant-current power supply 9A and the body resistance potential detector 9B constitute impedance measuring unit 9. The support base 2 has a group of setting keys 5, which serve as an input unit for entering information of a subject of measurement, and liquid crystal display 6 serving as an information unit. Cable 7 connects handgrip unit 4 to the support base 2 in order to maintain an electrical connection between hand electrodes 3A and 3B and the impedance measuring unit 9. The storage unit 8 disposed to an exterior of the support base 2 has a cylindrical shape provided with a sufficient volume to house the entire cable 7 in it and an opening area for insertion of the handgrip unit 4. The storage unit 8 thus defines a holder for holding the handgrip unit 4 integrally with the support base 2. The hand electrodes 3A and 3B constructed of electrically conductive metallic material wrap around the handgrip unit 4 and secured to it. The electrode 3A serves the other end of the electric terminals of the constant-current power supply 9A, and the electrode 3B serves the other end of the body resistance potential detector 9B. A person, i.e. subject of measurement 10, holds the handgrip unit 4 and steps on the support base 2 with bare feet, as shown in FIG. 3. With the subject of measurement 10 in this posture, his/her palm comes in contact to the hand electrodes 3A and 3B, and soles of his/her feet come in contact to the foot electrodes 1A, 1B, 1C, and 1D.

As illustrated in FIG. 2, the foot electrodes 1A, 1B, 1C and 1D and the hand electrodes 3A and 3B are connected to the impedance measuring unit 9. The impedance measuring unit 9 supplies through the constant-current power supply 9A a constant current between one electric terminal of the connected foot electrodes 1A and 1B and another electric terminal of the hand electrode 3A. The body resistance potential detector 9B then measures a voltage potential between the foot electrodes 1C and 1D and the hand electrode 3B using a four-terminal method. The apparatus thus measures impedance. In this exemplary embodiment, the apparatus uses a weak current of 500 μA at frequency of 50 kHz, which is not sensible by human body. Microcomputer 11 defining a computing unit receives the measured impedance. The group of keys 5 and the liquid crystal display 6 are connected with the microcomputer 11.

In this embodiment, although the electrodes 1A and 1B, and another set of electrodes 1C and 1D are connected together respectively, as described, this structure may be replaced by a combination of only two electrodes 1A and 1C, without providing other electrodes 1B and 1D, or a combination of only two electrodes 1B and 1D, without providing the other electrodes 1A and 1C. Measurement of the impedance between hand and foot can be made even with any of such structures. Furthermore, in the described embodiment, the impedance measuring unit 9 uses electrodes 1A, 1B and 3A for the electric terminals of the constant-current power supply 9A, and electrodes 1C, 1D and 3B for the electric terminals of the body resistance potential detector 9B. However, the electrodes 1C, 1D and 3B may be used for the electric terminals of the constant current source 9A, and the electrodes 1A, 1B and 3A for the electric terminals of the body resistance potential detector 9B, to perform the measurement of impedance. To simplify the following descriptions, the foot electrodes 1A, 1B, 1C and 1D are called collectively as foot electrode 1, and the hand electrodes 3A and 3B are called collectively as hand electrode 3.

Operation and function of the apparatus according to this exemplary embodiment will now be described hereinafter.

Prior to measurement, the subject of measurement 10 uses the group of keys 5 to enter his/her height, weight and sex, as information on the subject of measurement. Because the group of keys 5 is connected with the microcomputer 11, the microcomputer 11 takes them as information on the subject of measurement. Next, the subject of measurement 10 holds the handgrip unit 4, with his/her arm extended horizontally as shown in FIG. 3, and steps on the support base 2. Under this condition, a palm of the subject of measurement 10 comes in contact to the hand electrode 3, and soles of the feet of the subject of measurement 10 come in contact to the foot electrode 1. The impedance measuring unit 9 measures impedance between the hand and the feet of the subject of measurement 10, since the foot electrode 1 and the hand electrode 3 are connected to the impedance measuring unit 9.

When the impedance measuring unit 9 inputs the impedance to the microcomputer 11, it calculates a percent of body fat from the impedance and other information of the subject of measurement by using a program. The result is output to the liquid crystal display 6.

Although there are a number of known formulae to obtain percent of body fat, this embodiment uses the Brozec's formula, for calculation of the percent of body fat from a body density (A report by Brozec et al., J. Brozec, F. Grande, J. T. Anderson and A. Key, “An NY Academy of Sciences 110” (1963) 113-40). It gives the following equations in the case of male body:

Body density=1.1554−0.0841×(body weight)×(impedance)/(height)²

Percent of body fat (%)=(4.95/(body density)−4.5)×100

Although these equations are for male bodies, they also apply to female bodies by changing only values of the individual coefficients, which can be switched according to the type of sex included in the information of the subject of measurement. In addition, since there are many formulae suggested to obtain percent of body fat, this apparatus can be adopted for use with any of them without departing from the spirit and scope of this invention as long as the formulae use impedance to obtain percent of body fat.

In this exemplary embodiment, although the apparatus displays a percent of body fat as is obtained from the impedance, it may also, or instead display any of a body fat mass, a lean body mass, and a percent of lean body, all obtainable from the percent of body fat. Furthermore, although the apparatus uses group of keys 5 as the input unit comprising a combination of an up-and-down switch and an input switch, it can be of any other means that can input necessary information of the subject of measurement. The input unit may be a group of ten keys or rotary-type input device using a rotary encoder and the like, for example. Moreover, although the liquid crystal display 6 is used as an information unit, it may be substituted by other information means such as ones that use light emitting diodes, audible voice, and the like. Also, the constant current can be changed arbitrarily to any amount of current and frequency so long as it is within a level not sensible by human body. In this exemplary embodiment, although the apparatus is shown as taking a measurement of impedance between right hand and both feet, the combination may be selected freely between left hand and both feet, right hand and right foot, right hand and left foot, left hand and right foot, left hand and left foot, and the like, as long as it can measure the impedance between the hand and the foot (feet).

The handgrip unit 4 used in this example is cylindrical in shape, which can be held in one hand. However, its shape is not restrictive, and any other shape is usable if it is easy to hold while maintaining a reliable contact between the hand and the hand electrode.

When the measurement is completed for percent of body fat according to the above procedure, the person, or the subject of measurement 10, stores the cable 7, which electrically connects the handgrip unit 4 used for the measurement to the support base 2, into the storage unit 8 disposed to the support base 2, by pushing it in, and inserts the handgrip unit 4 also into the storage unit 8. The cable 7 connecting the handgrip unit 4 to the support base 2 is stored in this manner into the storage unit 8 when the apparatus is not in use, as shown in FIG. 4. The cable 7, which tends to come loose, can be put in order neatly and sightly by simply pushing it into the storage unit 8. This makes the entire apparatus in good order for storage, so as to prevent it from becoming disorderly when not in use, and to avoid such troubles as the cable 7 getting caught when moving the apparatus. Furthermore, the handgrip unit 4 can serve as a cap of the opening in the storage unit 8 after the cable 7 is stored, since the handgrip unit 4 is inserted into the opening following the insertion of cable 7. Because the cable 7 is stored out of sight, the entire apparatus appears neatly. In addition, the cable 7 does not become dirty so easily because dust is unlikely to get into the storage unit 8, thereby alleviating the task of cleaning.

(Second Exemplary Embodiment)

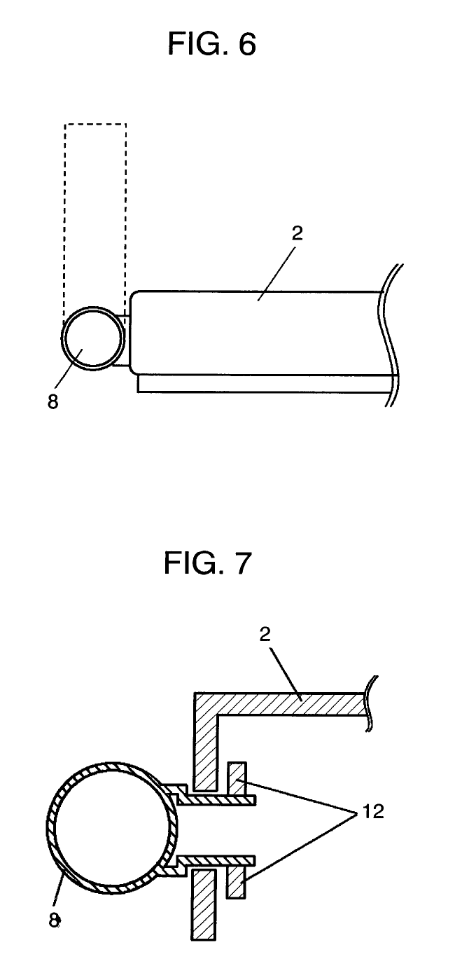

FIG. 5 is a front view of a body data measuring apparatus according to the second exemplary embodiment of this invention, as viewed from one side facing storage unit 8, wherein broken line shows the storage unit 8 in a position when it is turned counterclockwise by 90 degrees. FIG. 6 is a right-side view of the same apparatus in the vicinity of the storage unit 8 as viewed from a direction of arrow A in FIG. 5, wherein broken line shows the storage unit 8 in the same position that it is turned counterclockwise by 90 degrees. FIG. 7 is a sectional view as taken along a line B-B of FIG. 5, illustrating as an example one of methods for mounting the cylindrical storage unit 8 to body support base 2 (hereinafter referred to as support base). Referring to FIG. 7, this example of mounting the storage unit 8 to the support base 2 will now be described hereinafter. A fitting portion of the storage unit 8 is inserted into a circular opening provided in the support base 2, and an annular stopper 12 serving as a fastener for preventing the storage unit 8 from slipping out of the opening is inserted and fixed in position on the cylindrical storage unit 8. The structure described here makes the storage unit 8 turnable about the center of the circular opening provided in the support base 2, as shown in FIG. 5 and FIG. 6. Other than the above, the apparatus has like structure as that described in the first exemplary embodiment.

According to this exemplary embodiment, as described above, the storage unit 8 can be turned to any desired angle. This provides the storage unit 8 with a high degree of flexibility in direction of the opening, such that the storage unit 8 can be set to the upright position, as shown with broken line in FIG. 5 when storing cable 7. Therefore, the user can take a comfortable position when storing in and taking out the handgrip unit 4 and the cable 7.

Also, the storage unit 8 can be turned into such a position that the side of it becomes level with a top surface of the support base 2 after the handgrip unit 4 and the cable 7 are stored, as shown with the solid line in FIG. 5, so as to keep the entire apparatus compact when not in use.

(Third Exemplary Embodiment)

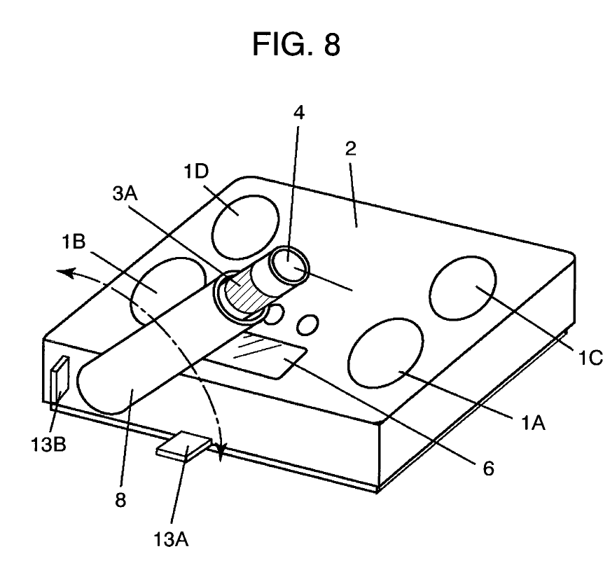

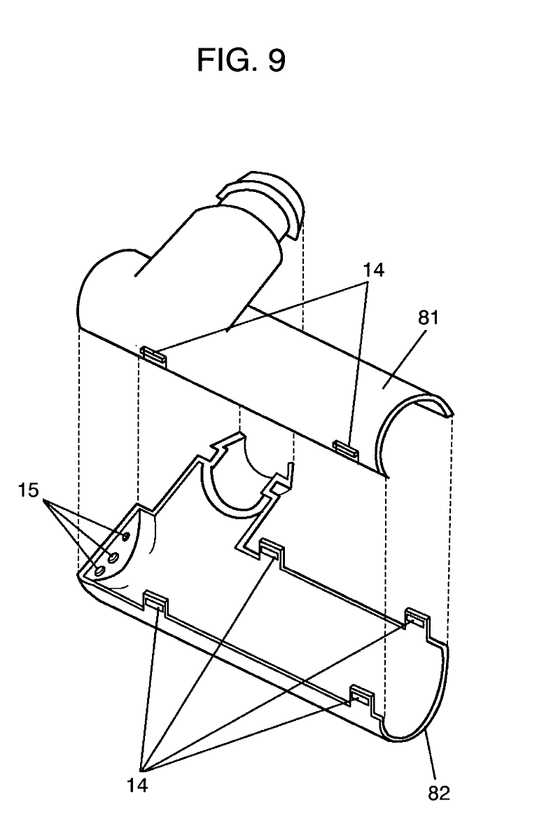

FIG. 8 is a general view of a body data measuring apparatus according to the third exemplary embodiment of this invention, wherein the apparatus is provided with stoppers for restricting a turnable range of the storage unit 8. The restraining stoppers 13A and 13B for restricting turning movement comprise projections, each having an enough length to come in contact with the side of the storage unit 8 when the storage unit 8 is turned to a predetermined position, and to prevent further movement of the storage unit 8. When the storage unit 8 is turned to a position (i.e. the position shown with solid line in FIG. 5), where it becomes level with a top surface of body support base 2 (“support base” hereinafter), the side of the storage unit 8 comes to contact the stopper 13A, and further movement is restricted. Also, when the storage unit 8 is turned to another position (i.e. the position shown with broken line in FIG. 5), where it becomes in parallel to the vertical side of the support base 2, the side of the storage unit 8 comes to contact the stopper 13B, and any further movement is again restricted. Structure other than the above is similar to that of the second exemplary embodiment.

Accordingly, since this structure restricts turning movement of the storage unit 8 within the range shown by arrow and dotted line in FIG. 8, it alleviates torsion and twist of the cable 7 connecting to the inside of the support base 2 through an interior of the storage unit 8 as small an extent as possible. It also prevents the storage unit 8 from being turned many times in the same direction, thereby avoiding the cable 7 from being disconnected by twisting off and the like. This structure can thus improve reliability of the cable against disconnection.

In this exemplary embodiment, the stoppers 13A and 13B are disposed to the support base 2. However, similar stoppers of projection and the like may be formed on an external surface of the storage unit 8.

(Fourth Exemplary Embodiment)

FIG. 9 is an exploded view of a storage unit of a body data measuring apparatus according to the fourth exemplary embodiment of this invention, as it shows a general view of storage unit 8 constructed of two members.

Upper semi-cylindrical member 81 and lower semi-cylindrical member 82 are combined to compose the storage unit 8. Hooks 14 engage and hold the semi-cylindrical members 81 and 82 together when they are assembled. Drain holes 15 are provided in a wall surface opposite an opening, through where cable 7 and handgrip unit 4 are inserted. They let out water and dust that may otherwise collect inside the cylindrical storage unit 8. Structure other than the above is similar to that of the second exemplary embodiment.

In a structure such as above, the storage unit 8 can be assembled with the cable 7 running through it, by simply attaching together the upper semi-cylindrical member 81 and the lower semi-cylindrical member 82 after placing the cable 7 between them. The structure comprising the two members to compose the storage unit 8 in this manner can substantially improve efficiency of the time consuming work to insert the cable 7 into the storage unit 8 during assembly of this apparatus.

Besides, the storage unit 8 is provided with the holes 15 in the wall surface opposite the opening through which the cable 7 and the handgrip unit 4 are stored. Because of these holes 15, water and dust can be discharged naturally from the inside to the outside of the storage unit 8 through the holes 15 even if the water and dust collect in the storage unit 8 when it is turned to the position in parallel to the vertical side of the body support base 2 (i.e. the position shown with broken line in FIG. 5), thereby maintaining the apparatus sanitary. As described, this structure allows dust and water, which is liable to enter into the storage unit 8, to discharge easily, reduces fouling on the cable 7, and alleviates the task of cleaning the same.

(Fifth Exemplary Embodiment)

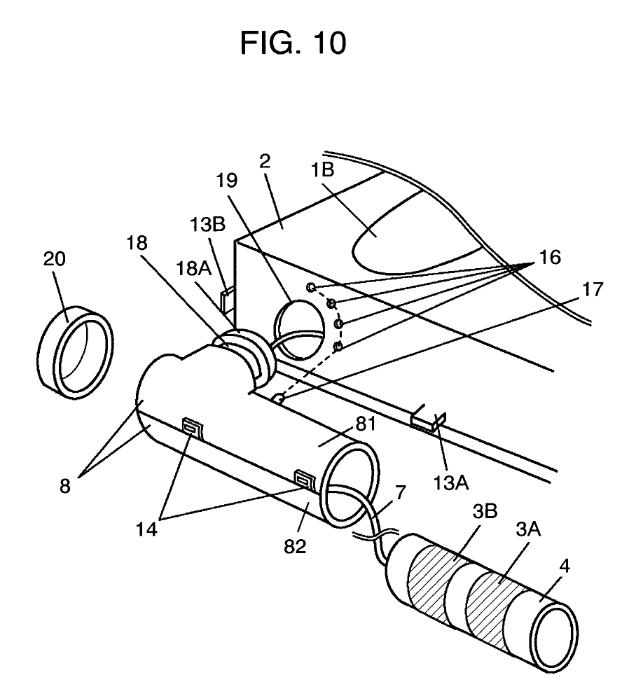

FIG. 10 is a general view of a body data measuring apparatus according to the fifth exemplary embodiment of this invention, depicting a position of storage unit 8 as being attached to body support base 2 (hereinafter referred to as support base). In this figure, the storage unit 8 has like structure as that of the fourth exemplary embodiment. An inner diameter of opening 19 for insertion of the storage unit 8 is a size large enough to receive fitting portion 18 having a diameter decreased from that of the storage unit 8, with a clearance of such an extent that does not impede turning of the storage unit 8.

Fitting end portion 18A with a tapered end has an outer diameter just appropriate for press-fit into the opening 19, and a difference in diameter of this fitting end portion 18A from the fitting portion 18 constitutes disengagement prevention means, after it is press-fit into the opening 19 in the support base 2.

When the storage unit 8 attached to the support base 2 is turned, boss 17 formed on the storage unit 8 is caught in one of recesses 16 provided in the support base 2, and it remains engaged in the recess 16 to lock the storage unit 8 in the given position. That is, the boss 17 on the storage unit 8, together with the recesses 16 in the support base 2 comprises a locking stopper.

Cap 20 closes an end face of the storage unit 8 opposite the opening through which the cable 7 and the handgrip unit 4 are stored.

In the structure described above, the storage unit 8 can be press-fit easily into the opening 19 when the storage unit 8 is made of a comparatively pliant material among many plastic resins such as polypropylene. This makes the opening 19 retain the upper semi-cylindrical member 81 and the lower semi-cylindrical member 82 together to keep them combined and never to allow them separate. The structure can thus reduce a number of man-hour required for assembling as well as a number of components to retain the integrity of the assembly.

On the other hand, since the storage unit 8 and the support base 2 are attached only by means of press-fit, the upper semi-cylindrical member 81 and the lower semi-cylindrical member 82 can be disassembled simply by disengaging the hooks 14 after the storage unit 8 is pulled out from the support base 2. The cable 7 and an interior of the storage unit 8 can be cleaned easily once they are disassembled.

Also, since the boss 17 is caught in engagement with one of the recesses 16 in given positions as the storage unit 8 is turned, the user can set the storage unit 8 to the desire, easy-to-use position for making a measurement, storage, and the like.

The storage unit 8 is also provided with cap 20 on the end face opposite the opening through which the cable 7 and the handgrip unit 4 are stored. The cap 20 prevents the stored cable 7 from slopping out of the storage unit 8 even when a large opening is provided in the end surface opposite the opening through which the cable 7 and the handgrip unit 4 are stored. The cap 20 normally prevents dust and water from entering, but it gives a large opening when removed to allow easy access to the interior of the storage unit 8 for cleaning and the like.

In this exemplary embodiment, the boss 17 is formed on the storage unit 8. However, this structure may be so reversed that a recess is provided in the storage unit 8, and a plurality of bosses are formed on the support base 2.

(Sixth Exemplary Embodiment)

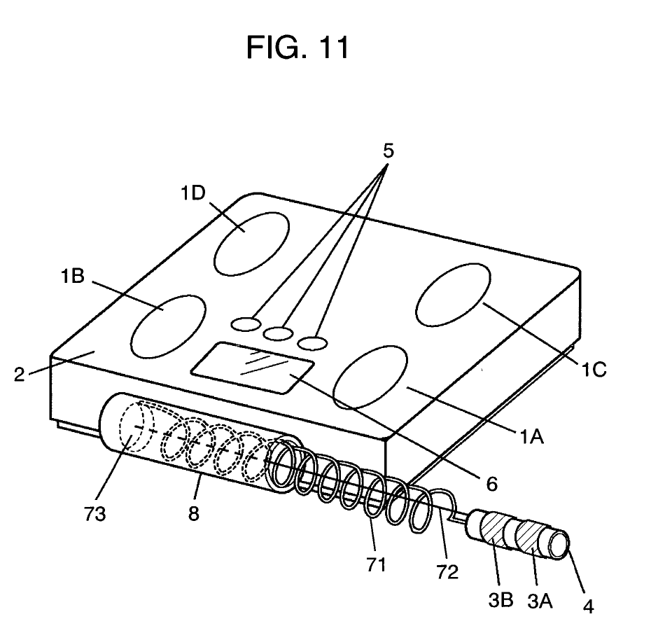

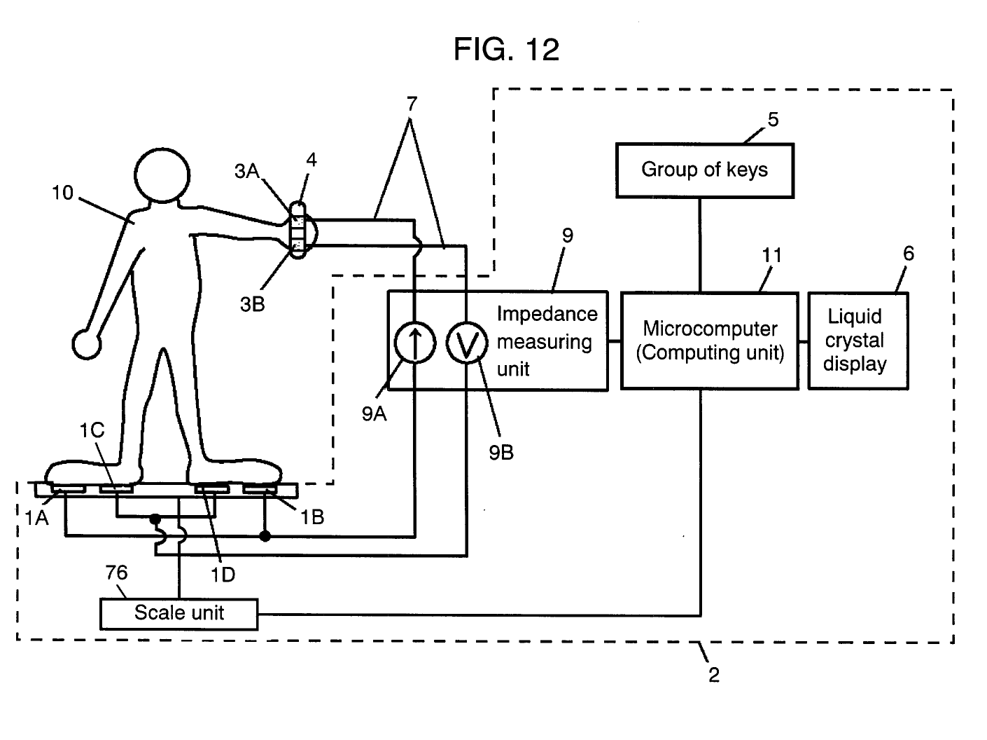

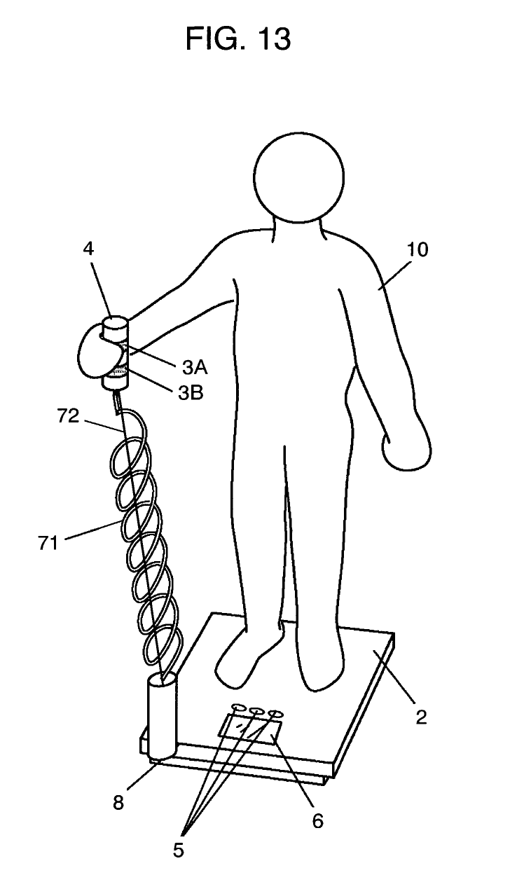

FIG. 11 is a general view of a body data measuring apparatus according to the sixth exemplary embodiment of this invention, FIG. 12 is a block diagram of the same, and FIG. 13 is an expository illustration showing how measurement is made.

In this exemplary embodiment, spiral cable 71 is used for connection of body support base 2 (hereinafter “support base”) to handgrip unit 4, as shown in FIG. 11, to maintain electrical continuity between hand electrodes 3A and 3B and impedance measuring unit 9. Storage unit 8 has an interior volume large enough to store the spiral cable 71, and an opening area for insertion of the handgrip unit 4. In addition, the storage unit 8 comprises winding unit 73 built in it for winding up wire 72, which runs through an inner space of the spiral cable 71. The support base 2 is provided with scale unit 76 for weighing a body weigh of the subject of measurement 10, as shown in FIG. 12. Structure other than the above is similar to that of the first exemplary embodiment.

The subject of measurement 10 pulls out the handgrip unit 4 from the storage unit 8 in order to take a position of measurement with his/her arm extended horizontally, as shown in FIG. 13. The spiral cable 71 expands at this time, and the wire 72 wound in the winding unit 73 is drawn out, as he/she steps on the support base 2. The scale unit 76 outputs to microcomputer 11 an output data necessary to compute a percent of body fat. Subsequently, the apparatus measures the percent of body fat in the same manner as described in the first exemplary embodiment.

After completing the above steps for measurement of the percent of body fat, the subject of measurement 10 relaxes the strain of holding the handgrip unit 4 used for the measurement, to let the winding unit 73 rewind and take the wire 72 into the storage unit 8. Since the wire 72 runs through the inner space of the spiral cable 71, the spiral cable 71 is also pulled into the storage unit 8 at the same time. As described, the spiral cable 71 can be stored automatically and easily into the storage unit 8 after the measurement, when the subject of measurement 10 simply relaxes the strain of holding the handgrip unit 4 upward. In other words, this structure simplifies the task of storing the spiral cable 71, and improves convenience of use.

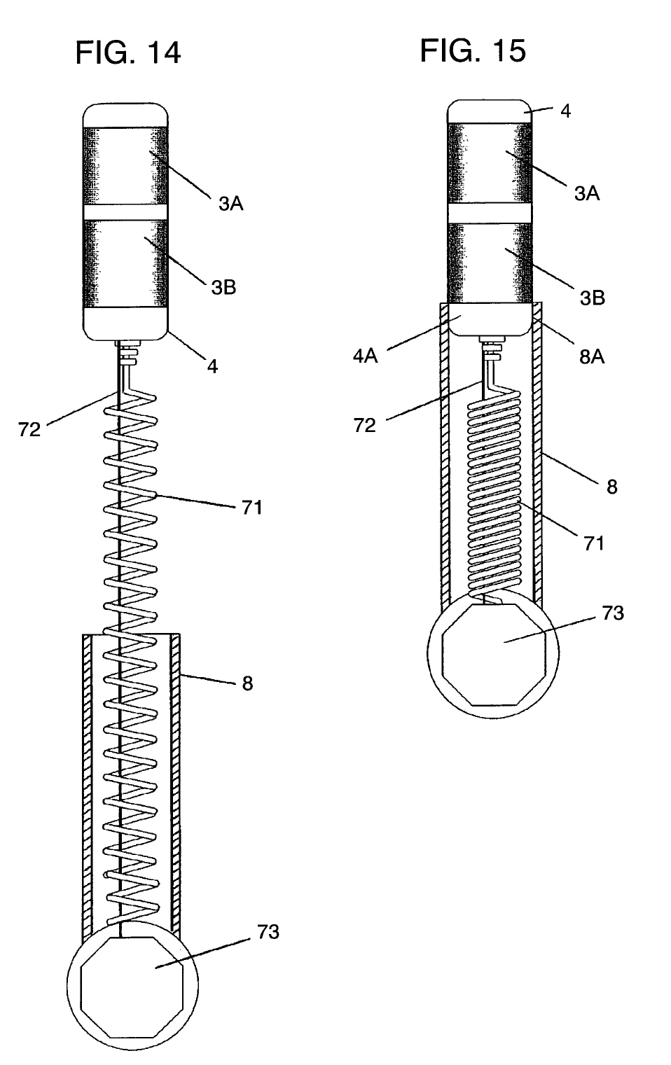

FIG. 14 is a schematic view depicting the spiral cable 71 and the wire 72 in their position of measurement when the handgrip unit 4 is pulled out. As the subject of measurement 10 pulls out the handgrip unit 4 to a desired position, the handgrip unit 4 pulls the wire 72 out of the winding unit 73 and expands the spiral cable 71.

FIG. 15 is another schematic view depicting the spiral cable 71 and the wire 72 in the stored position. When the subject of measurement 10 loosens the strain of holding the handgrip unit 4 to a force weaker than a tensile force of the winding unit 73, the winding unit 73 begins to take up the wire 72. Since the wire 72 is connected to the handgrip unit 4 and runs through in the spiral cable 71, the spiral cable 71 extended from the storage unit 8 is stored by contracting itself, as the wire 72 is taken up by the winding unit 73.

The handgrip unit 4 is provided on its one end with fitting portion 4A of such a shape that fits in opening 8A of the storage unit 8, and this fitting portion 4A serves as a cap of the opening 8A once the spiral cable 7 is stored. Therefore, dust and the like particles are not likely to enter inside of the cable storage unit when not in use, and this can further alleviate the task of cleaning since the spiral cable does not become dirty so easily.

In this exemplary embodiment, the winding unit 73 has been described as such that it takes up the wire with a predetermined force. However, the winding unit 73 may be so constructed that it locks itself after the wire is pulled out to any desired length, and rewinds the wire when the wire is pulled again, or that it rewinds the wire only when a rewind button is pushed. Such design eases the user to hold the handgrip unit 4 and improves convenience of use, since the winding unit 73 does not put the handgrip unit 4 under the strain during measurement.

Also, what has been described above is an example in which the winding unit 73 is assembled inside of the storage unit 8, and the storage unit 8 attached to the support base 2. However, the storage unit 8 may be mounted to the handgrip unit 4, so that rewinding of the wire 72 can contract the spiral cable 71 for storage into the storage unit 8.

Alternatively, the winding unit 73 may be assembled into any of the support base 2 and the handgrip unit 4. In this case, one end of the spiral cable 71, i.e. the end to be pulled out, is connected to the other one of the support base 2 and the handgrip unit 4, in a manner that the wire 72 runs through the inner space of the spiral cable 71. Hence, rewinding of the wire 72 can contract the spiral cable 71 for storage into the storage unit 8.

Since the scale unit is built into the support base 2, it takes body weight for use as a part of information for the subject of measurement, so as to alleviate a task of entering the weight data when he/she inputs the information representing his/her physical characteristics.

(Seventh Exemplary Embodiment)

A body data measuring apparatus of the seventh exemplary embodiment is similar to the one shown in the sixth exemplary embodiment, except that it employs a turning mechanism of the storage unit 8 as illustrated in the second exemplary embodiment.

The apparatus so constructed according to this exemplary embodiment allows the cable storage unit to be turned freely to any desired angle. Thus, the handgrip unit 4 can be taken out or stored easily when taking a measurement as shown in FIG. 13.

Also, the storage unit 8 is turned into such a position that the side of it becomes level with a top surface of the body support base 2 after the spiral cable 71 and the handgrip unit 4 are stored in the same manner as the second exemplary embodiment, when the apparatus is not in use. This keeps the entire apparatus compact and neat.

(Eighth Exemplary Embodiment)

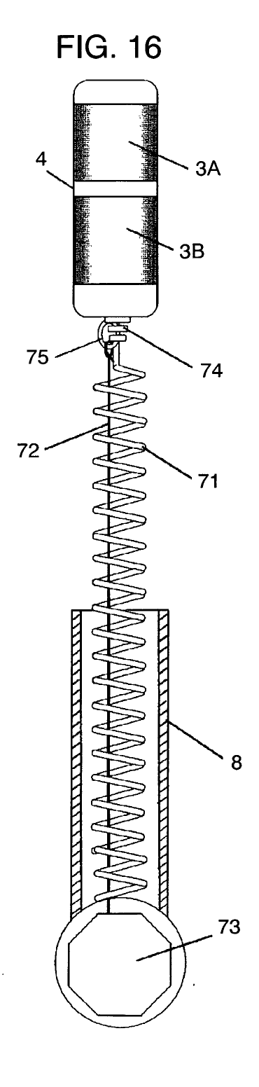

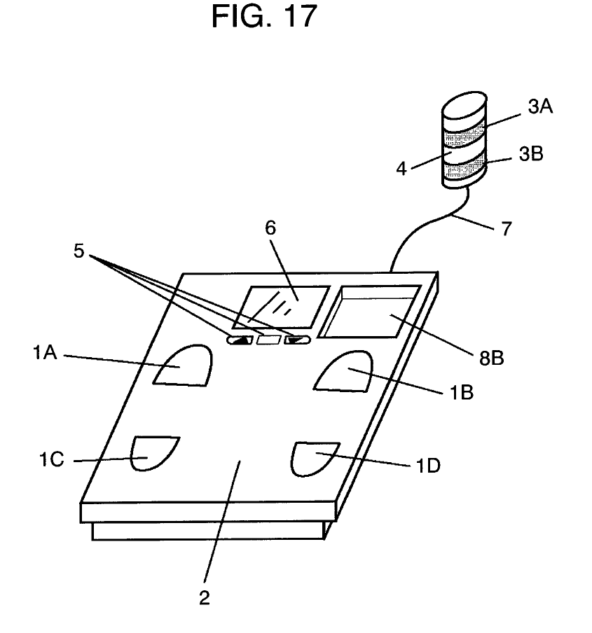

FIG. 16 illustrates a method of connecting wire 12 in the body data measuring apparatus according to the eighth exemplary embodiment of this invention. Bushing 74 protects spiral cable 71.from being disconnected due to flexing when handgrip unit 4 is moved arbitrary into any position during handling. Annularly shaped fastener 75 is formed integrally with the bushing 74. The handgrip unit 4 of a shape illustrated here in this exemplary embodiment is assembled in the following manner. First, two plastic parts of semi-cylindrical shape are combined together to form a cylindrical shape. During this assembling process, the bushing 74 is placed between the two semi-cylindrical parts, and electrical connection is made inside of the two parts for terminals of conductors from the spiral cable 71. After the handgrip unit 4 is assembled, wire 72 is set inside of the spiral cable 71, and one end of the wire 72 is securely fixed to the fastener 75 by means of binding and the like. The structure as constructed above provides for handling efficiency during assembling process and improves productivity as compared to other structure that requires fixation of the wire 72 under a tension of the winding unit 73 to the interior of the handgrip unit 4.

As discussed above, the body data measuring apparatuses according to the sixth through the eighth exemplary embodiments facilitate storage since they retracts the spiral cable 71 automatically into the storage unit 8 by simply loosening the strain of holding the handgrip unit when the measurement is completed. Moreover, the entire apparatus can be put in proper order for storage, which is otherwise liable to become disorderly in appearance because of the unsteadily snaky spiral cable 71. Furthermore, since the spiral cable 71 is housed in the storage unit 8, the apparatus reduces possibility of the spiral cable 71 getting dirty and thus alleviates the task of cleaning. In addition, since the wire 72 is also housed in the storage unit 8, to avoid the spiral cable 71 from hanging down or being caught, the apparatus can be carried easily without trouble.

Also, since the storage unit 8 is freely turnable to any angle, the handgrip unit 4 can be taken out easily when in use, and stored compactly for storage of the apparatus.

Furthermore, since the bushing 74 is provided with the fastener 75, the apparatus can be produced efficiently.

(Ninth Exemplary Embodiment)

FIG. 17 is a general view of a body data measuring apparatus according to the ninth exemplary embodiment of this invention. Outward appearance of this apparatus is similar to that of the first exemplary embodiment except that it has storage space 8B within body support base 2.

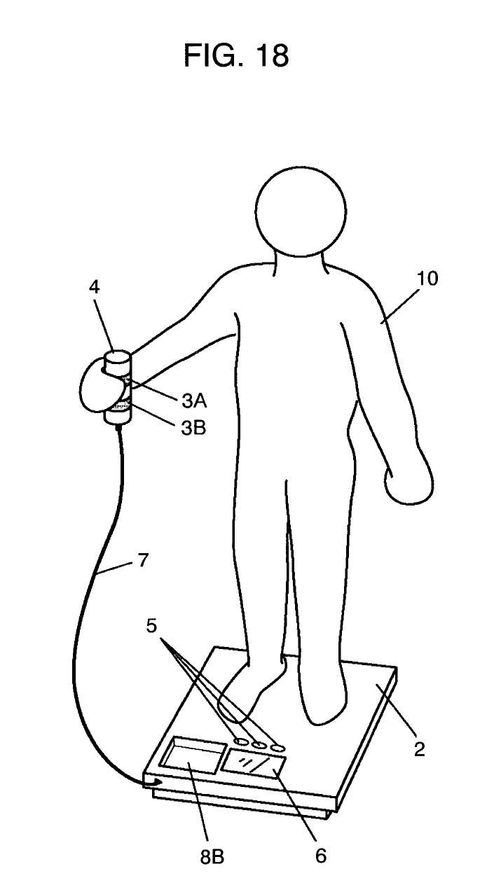

Subject of measurement 10 holds handgrip unit 4 and steps on the body support base 2 (hereinafter referred to as support base) with bare feet, as shown in FIG. 18. While the subject of measurement 10 takes this posture, his/her palm comes in contact to hand electrodes 3A and 3B, and tiptoes and heels in soles of his/her feet come in contact to foot electrodes 1A, 1B, 1C, and 1D respectively. In the same manner as the first exemplary embodiment, the foot electrodes 1A, 1B, 1C and 1D are called collectively as foot electrode 1, and the hand electrodes 3A and 3B are called collectively as hand electrode 3, to simplify the explanation below.

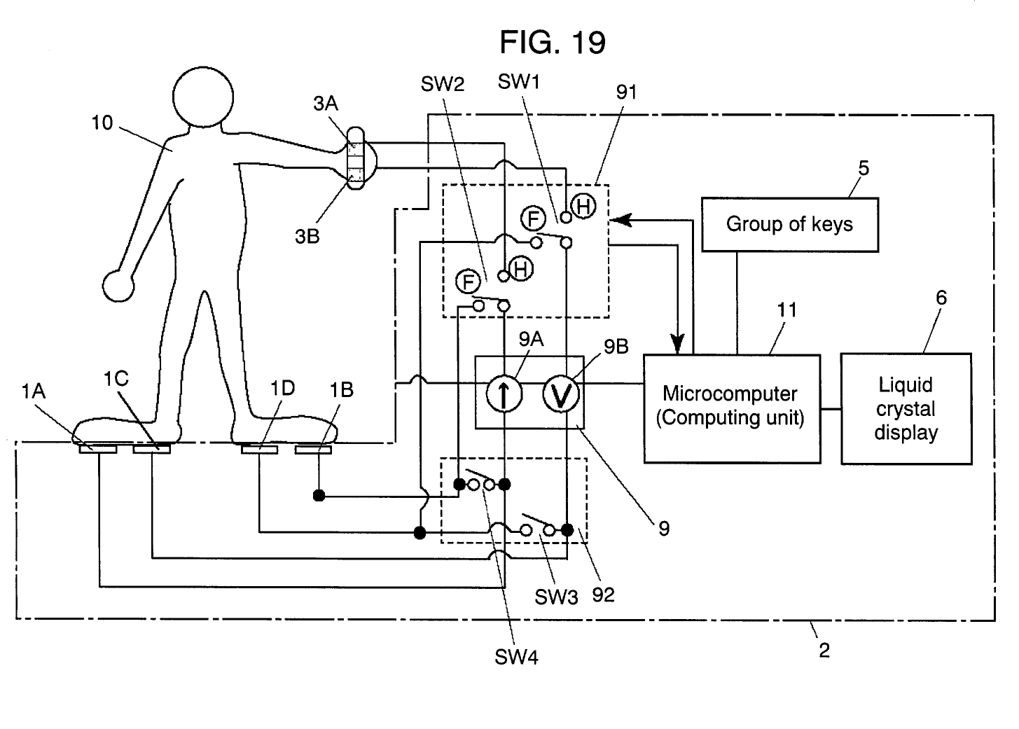

FIG. 19 depicts a block diagram of an interior of the support base 2. Referring now to FIG. 19, an operation sequence in the measurement will be described hereinafter.

At the start of measurement, microcomputer 11 defining a computing unit sends a signal to switching units 91 and 92 to open SW3 and SW4, and to set connections of SW1 and SW2 to F sides. The microcomputer 11 then measures impedance between the both feet according to the four-terminal method by using impedance measuring unit 9.

After confirmation that the subject of measurement 10 is firmly in contact with the foot electrode 1 on the support base 2, and that the impedance measured here has a value within a predetermined range, a scale unit similar to that of the sixth exemplary embodiment (not show in the figure) weighs a body weight of the subject of measurement. Subsequently, the microcomputer 11 closes SW3 and SW4, sets connections of SW1 and SW2 to H sides, and measures impedance between the hand and the both feet according to the four-terminal method. The impedance measuring unit 9 operates and a percent of body fat is computed in the same manner as described in the first exemplary embodiment.

When the subject of measurement 10 completed measurement of the percent of body fat using the above method, he/she stores the cable 7 used for the measurement into the storage space 8B provided in the support base 2 by either pushing it forcibly or placing it in a bundle.

In this exemplary embodiment, although the storage space 8B is provided within the support base 2, it may be constructed of a separate component and attached to the support base 2 in the like manner as the storage units of the first to the eighth exemplary embodiments. In addition, although the storage space 8B shown here has a recessed portion configuration, this is not restrictive and it can be of any shape so long as it can accommodate the handgrip unit and the cable.

Also, a measuring sequence of the microcomputer 11 may be designed switchable according to presence and absence of the switching units. When this is the case, most of the related control circuit can be used commonly as with the apparatuses of the first through the eighth exemplary embodiments having the support base 2 of a shape large enough to spaciously support the subject of measurement 10. Therefore, this embodiment can increase the merit of mass production.

(Tenth Exemplary Embodiment)

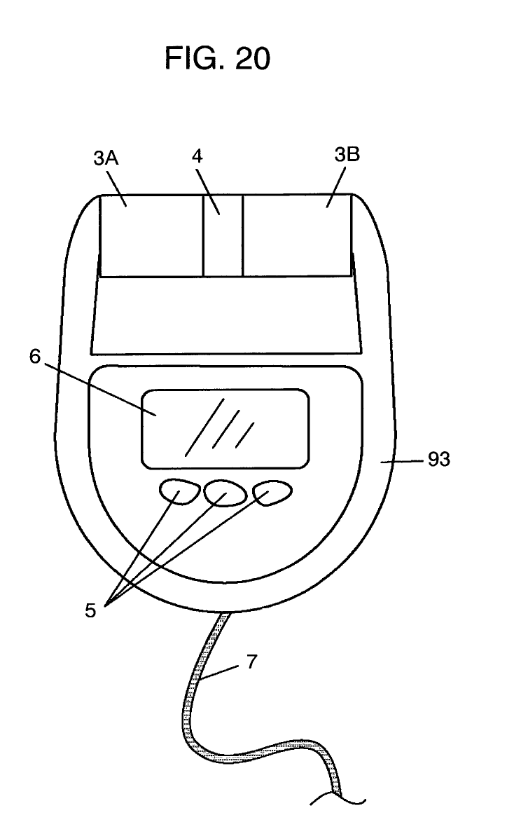

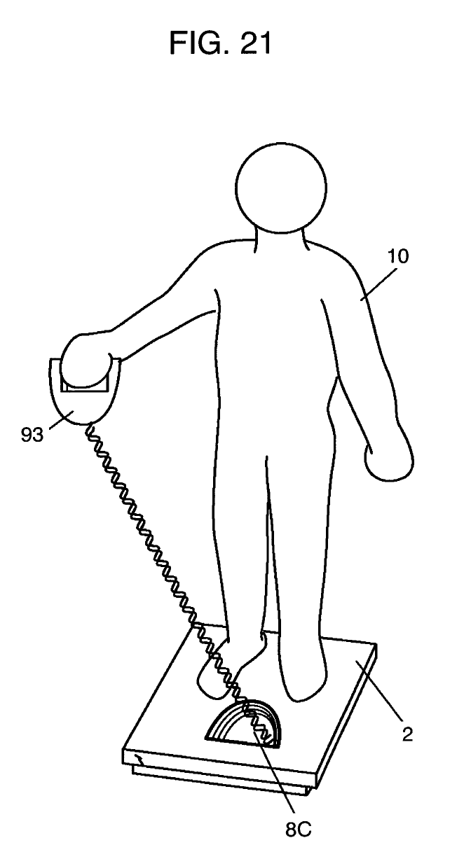

FIG. 20 is an overall view of a handgrip unit of a body data measuring apparatus according to the tenth exemplary embodiment of this invention, and FIG. 21 is an expository illustration showing the same being in use. This apparatus differs from that of the ninth exemplary embodiment in respect that it comprises a hand-held controller 93 provided with liquid crystal display 6 defining an information unit, a group of keys 5 defining an input unit, and handgrip unit 4, all in one body. In this embodiment, the hand-held controller 93 is constructed by integrating the liquid crystal display 6 and the group of keys 5 serving as an input unit into the handgrip unit 4 similar to that of the ninth exemplary embodiment, and connecting it to body support base 2 (hereafter referred to as support base) with cable 7, so as to improve convenience of use. The handgrip unit 4 is held in one hand as shown in FIG. 21, but it can be brought closer to eyes than the way shown in FIG. 21 when necessary to read the display 6. According to this exemplary embodiment, one needs not to bend down to read the display 6, and still finds a result of measurement correctly without having an error in reading the result.

In the hand-held controller 93 of this exemplary embodiment, although the group of keys 5 serving as input unit is arranged below the display 6 serving as information unit, any other arrangement is possible without restriction so long as they are provided integrally with the controller 93. Upon completion of the measurement of a percent of body fat using the above method, the subject of measurement 10 stores the cable 7 used for the measurement into storage space 8C, a recessed portion, provided in the support base 2 by either pushing it forcibly or placing it in a bundle. This makes the entire apparatus neat and straight when in storage, and avoids the apparatus from becoming disorderly when not being used.

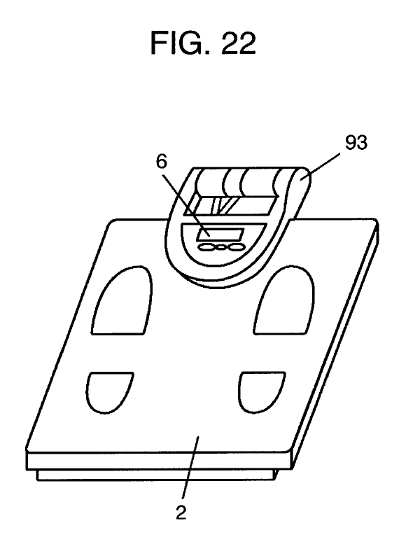

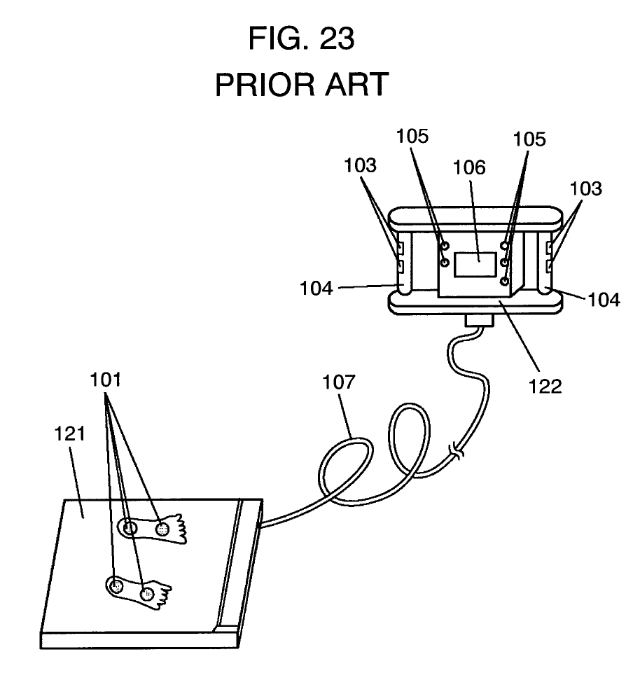

FIG. 22 is an overall view of the apparatus when the hand-held controller 93 is stored in the support base 2. As shown in the figure, the controller 93 functions as a lid when stored, to cover an entire opening of the storage space 8C provided in the support base 2. After the measurement of body fat is completed and the cable 7 stored in the storage space 8C provided in the support base 2 by either pushing it or placing it in a bundle, the hand-held controller 93 is placed in alignment to the opening of the storage space 8C. Thus, the controller 93 conceals the storage space 8C entirely out of sight including the cable 7 even when the cable 7 looks disorderly due to it having been pushed in by force in the storage space 8C. Also, since dust and the like particles are not likely to enter the storage space 8C, the cable does not become dirty so easily and this alleviates the task of cleaning. Accordingly, this makes the entire apparatus even more neat and straight than that of the ninth exemplary embodiment.

According to any of the ninth and the tenth exemplary embodiments, as described, the body data measuring apparatus can reduce variations in measurement of weight and body impedance, since it starts the measurement only after the confirmation that the subject of measurement is in a stable posture for measurement.

What is claimed is:

1. A body data measuring apparatus comprising:
a body support base provided with a foot electrode for making contact with foot of a subject of measurement, said body support base for getting thereon said subject when taking a measurement;
a handgrip unit provided with a hand electrode for making contact with a hand of said subject, said handgrip unit for being held by said subject when taking the measurement;
an impedance measuring unit for measuring impedance between said foot electrode and said hand electrode;
an input unit for receiving input information on said subject representing physical characteristic of said subject;
a computing unit for computing physical data on body of said subject based on said impedance between said foot electrode and said hand electrode and said information on said subject;
an information unit for indicating a result computed by said computing unit;
a cable connecting said handgrip unit to said body support base; and
a holder for retaining said handgrip unit together with said body support base.

2. The body data measuring apparatus according to claim 1, wherein said holder has an opening for inserting at least said cable, and comprises a storage unit for storing at least said cable.

3. The body data measuring apparatus according to claim 2, wherein said storage unit has a cylindrical shape.

4. The body data measuring apparatus according to claim 2, wherein said storage unit receives said handgrip unit as a cap of said opening after said cable is inserted.

5. The body data measuring apparatus according to claim 2, wherein said storage unit is attached in a turnable manner to said body support base.

6. The body data measuring apparatus according to claim 5, further comprising a restraining stopper limiting a turnable range of said storage unit.

7. The body data measuring apparatus according to claim 5 further comprising a locking stopper disposed to at least one of said body support base and said storage unit, for locking said storage unit at a given position.

8. The body data measuring apparatus according to claim 2, wherein said storage unit comprises at least two members.

9. The body data measuring apparatus according to claim 8 further having a hook for retaining integrity of said at least two members when combined together.

10. The body data measuring apparatus according to claim 8, wherein said storage unit comprises a fitting portion when said at least two members are combined, and said fitting portion engages with an opening provided in said body support base.

11. The body data measuring apparatus according to claim 2, wherein said storage unit has a face with a hole opposite said opening, said hole having a size to prevent said cable stored in said storage unit from slipping out therethrough.

12. The body data measuring apparatus according to claim 2, wherein said storage unit comprises a removable cap on a face opposite said opening.

13. The body data measuring apparatus according to claim 1, wherein said cable comprises a freely expandable spiral cable.

14. The body data measuring apparatus according to claim 13 further comprising a wire running through an inner space of said spiral cable and a winding unit for said wire.

15. The body data measuring apparatus according to claim 14, wherein:
said wire and said spiral cable are disposed to run through in said holder;
said winding unit is attached to one of said handgrip unit and said body support base; and
a end of said wire other of the end wound in said winding unit is connected to the other of said handgrip unit and said body support base.

16. The body data measuring apparatus according to claim 15, wherein:
said holder is disposed to said body support;
said winding unit is attached to said holder; and
said end of said wire other of the end wound in said winding unit is connected to said handgrip unit.

17. The body data measuring apparatus according to claim 15, wherein:
said holder is disposed to said handgrip unit;
said winding unit is attached to said holder; and
said end of said wire other of the end wound in said winding unit is connected to said body support base.

18. The body data measuring apparatus according to claim 15 further comprising a fastener for connecting said end of said wire other of the end wound in said winding unit.

19. The body data measuring apparatus according to claim 14, wherein:
said holder has an opening for inserting at least said cable, and comprises a storage unit for storing at least said cable; and
any of said handgrip unit and said body support base not fixed with said storage unit has a fitting portion for fitting with said opening of said storage unit.

20. The body data measuring apparatus according to claim 1, wherein said body support base further comprises a scale unit built therein for weighing a body.

21. The body data measuring apparatus according to claim 1, wherein each of said foot electrode and said hand electrode comprises at least two electrically isolated electrodes.

22. The body data measuring apparatus according to claim 1, wherein:
said foot electrode comprises at least four electrically isolated electrodes;
said hand electrode comprises at least two electrically isolated electrodes;
said apparatus further comprises a switching unit for closing and opening continuities of any two pairs of said foot electrodes simultaneously; and
said switching unit is controlled for selecting any one of measurement taken only with said foot electrodes and another measurement taken with both said foot electrodes and said hand electrodes.

23. The body data measuring apparatus according to claim 22, wherein:
said four foot electrodes makes contact with tiptoes and heels of both feet of said subject of measurement respectively; and
said switching unit closes and opens continuities between two of said foot electrodes in contact with the tiptoes and continuities between the other two of said foot electrodes in contact with the heels.

24. The body data measuring apparatus according to claim 22, wherein said apparatus determines whether impedance measured only with said foot electrodes has a value within a predetermined range of impedance.

25. The body data measuring apparatus according to claim 24, wherein said apparatus closes said switching unit and selects the measurement with both said foot electrodes and said hand electrodes, after determination that the impedance measured only with said foot electrodes is in value within said predetermined range of impedance.

26. The body data measuring apparatus according to claim 2, wherein said storage unit comprises a recessed portion provided in said body support base.

27. The body data measuring apparatus according to claim 26 further comprising a hand-held controller provided integrally with said handgrip unit, said input unit, and said information unit.

28. The body data measuring apparatus according to claim 27, wherein said recessed potion houses said cable, and said hand-held controller provides for a lid of said recessed potion.

29. The body data measuring apparatus according to claim 1, wherein said information unit comprises a display device.
